(19) United States
(12) Patent Application Publication
(10) Pub. No.: US 2015/0028963 A1
(43) Pub. Date: Jan. 29, 2015

(54) ELECTRONIC CIRCUIT

(71) Applicant: TAIYO YUDEN CO., LTD., Tokyo (JP)

(72) Inventors: Hitoshi EBIHARA, Tokyo (JP); Hiroshi HARA, Tokyo (JP)

(73) Assignee: TAIYO YUDEN CO., LTD., Tokyo (JP)

(21) Appl. No.: 14/333,014

(22) Filed: Jul. 16, 2014

(30) Foreign Application Priority Data
Jul. 23, 2013 (JP) 2013-153031
Jul. 30, 2013 (JP) 2013-158307

(51) Int. Cl. H03H 7/46

(52) U.S. Cl. CPC H03H 7/465
USPC 333/126; 333/103

(57) ABSTRACT

An electronic circuit includes: a switch including ports and selecting a port to be connected to an antenna from the ports; a first filter connected between a first port out of the ports and a first terminal; a second filter connected between a second port out of the ports and a second terminal and having a frequency band different from a frequency band of the first filter; and an impedance matching unit of which a first end is coupled to a third port out of the ports.

### CROSS-REFERENCE TO RELATED APPLICATION

This application is based upon and claims the benefit of priority of the prior Japanese Patent Application No. 2013-153031, filed on Jul. 23, 2013, and the prior Japanese Patent Application No. 2013-158307, filed on Jul. 30, 2013, the entire contents of which are incorporated herein by reference.

### FIELD

A certain aspect of the present invention relates to an electronic circuit.

### BACKGROUND

Communication devices such as mobile phones have extended their capabilities including a connection to the Internet. To address the increase in communication data, technology such as LTE (Long Term Evolution)-Advanced has been developed. In LTE-Advanced, CA (Carrier Aggregation) is employed to achieve high throughput. In CA, multiple frequency bands are simultaneously used. For example, in Inter-band CA, multiple frequency bands are shared to widen the band and to increase speed and the amount of data. A module supporting CA uses multiple filters or multiple duplexers to share multiple frequency bands. When a first duplexer have high impedance in the passband of a second duplexer, the loss of a signal is reduced, and good frequency characteristics can be obtained. Japanese Patent Application Publication Nos. 10-247801 and 2012-28895 disclose technology that makes it possible to achieve high impedance between duplexers. A module supporting three or more frequency bands includes a switch and multiple duplexers or multiple filters. The switch selects one of three or more duplexers or filters depending on a frequency band, and connects it to an antenna.

However, it has been difficult to make a single duplexer or filter have high impedance in two frequency bands. In addition, it has been difficult to make the duplexer have high impedance in a frequency band having large spacing between transmit and receive bands. When the impedance is not optimized, the signal leaks. As a result, frequency characteristics deteriorate.

### SUMMARY OF THE INVENTION

According to an aspect of the present invention, there is provided an electronic circuit including: a switch including ports and selecting a port to be connected to an antenna from the ports; a first filter connected between a first port out of the ports and a first terminal; a second filter connected between a second port out of the ports and a second terminal and having a frequency band different from a frequency band of the first filter; and an impedance matching unit of which a first end is coupled to a third port out of the ports.

### BRIEF DESCRIPTION OF THE DRAWINGS

FIG. 1 is a block diagram illustrating an electronic circuit in accordance with a first embodiment;

FIG. 2 is a block diagram illustrating an example of No. 1 in Table 1;

FIG. 3A is a block diagram illustrating an example of No. 4, and FIG. 3B and FIG. 3C are Smith charts illustrating impedance of a duplexer;

FIG. 4A is a block diagram illustrating an example of No. 5, and FIG. 4B and FIG. 4C are Smith charts illustrating impedance of a duplexer;

FIG. 5A is a block diagram illustrating an electronic circuit in accordance with a comparative example, and FIG. 5B and FIG. 5C are Smith charts illustrating impedance of a duplexer;

FIG. 6 is a block diagram illustrating an electronic circuit in accordance with a variation of the first embodiment;

FIG. 7 is a circuit diagram illustrating a matching circuit;

FIG. 8 is a block diagram illustrating an electronic circuit in accordance with a second embodiment;

FIG. 9 is a block diagram illustrating an electronic circuit in accordance with a third embodiment;

FIG. 10 is a schematic view illustrating frequencies of each band;

FIG. 11 is a block diagram illustrating an example of No. 51;

FIG. 12A is a block diagram illustrating an example of No. 54, and FIG. 12B and FIG. 12C are Smith charts illustrating impedance of a duplexer;

FIG. 13A is a block diagram illustrating an example of No. 55, and FIG. 13B is a Smith chart illustrating impedance of a filter;

FIG. 14A is a block diagram illustrating an example of No. 56, and FIG. 14B and FIG. 14C are Smith charts illustrating impedance of a duplexer;

FIG. 15 is a block diagram illustrating an electronic circuit in accordance with a fifth embodiment; and

FIG. 16 is a circuit diagram illustrating a matching circuit.

### DETAILED DESCRIPTION

A description will now be given of embodiments with reference to the drawings.

### First Embodiment

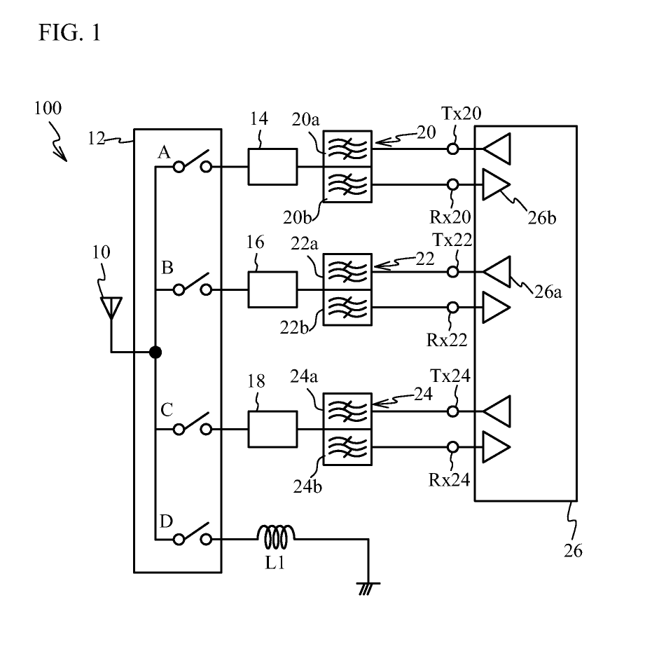

A first embodiment optimizes impedance by using an inductor L1. FIG. 1 is a block diagram illustrating an electronic circuit 100 in accordance with a first embodiment. As illustrated in FIG. 1, the electronic circuit 100 includes a switch 12, matching circuits 14, 16 and 18, duplexers 20, 22 and 24, and an integrated circuit (IC) 26. The IC 26 includes power amplifiers (PA) 26a and low noise amplifiers (LNA) 26b. The IC 26 performs signal processing such as up-conversion and down-conversion. The PA 26a amplifies a transmission signal. The LNA 26b amplifies a reception signal. The electronic circuit 100 is used in a module for communication devices, for example.

The duplexer 20 (a third duplexer) includes a transmit filter 20a and a receive filter 20b. The duplexer 22 (a first duplexer) includes a transmit filter 22a and a receive filter 22b. The duplexer 24 (a second duplexer) includes a transmit filter 24a and a receive filter 24b. Each filter is a bandpass filter such as a surface acoustic wave (SAW) filter.

The switch 12 is a semiconductor switch including four ports A˜D. A first end of the matching circuit 14 is coupled to the port A (a fourth port), and a second end is coupled to first ends of the transmit filter 20a and the receive filter 20b. A second end of the transmit filter 20a is coupled to the PA 26a through a transmit terminal Tx20 (a third terminal). A second end of the receive filter 20b is coupled to the LNA 26b through a receive terminal Rx20 (a third terminal). The port B (a first port), the matching circuit 16, the duplexer 22, a transmit terminal Tx22 and a receive terminal Rx22 (first terminals), the PA 26a, and the LNA 26b are connected in the same manner as the port A through the IC 26. The port C (a second port), the matching circuit 18, the duplexer 24, a transmit terminal Tx24 and a receive terminal Rx24 (second terminals), the PA 26a, and the LNA 26b are connected in the same manner as the port A through the IC 26. The matching circuits 14, 16, and 18 match impedance between the duplexers and impedance between an antenna 10 and each duplexer. A first end of the inductor L1 (a first matching circuit) is coupled to the port D (a third port), and a second end is grounded.

The duplexers support frequency bands different from each other. The duplexer 20 supports, for example, W-CDMA (Wideband Code Division Multiple Access) Band3. The duplexer 22 supports, for example, W-CDMA Band1. The duplexer 24 supports, for example, W-CDMA Band1. Hereinafter, Band may be solely described without describing W-CDMA.

A description will be given of transmission and reception of signals. The switch 12 selects a port from the ports A˜D depending on the frequency band to be used, and connects it to the antenna 10. Table 1 presents a relationship between frequency bands and ports.

TABLE 1

| | |
|---|---|
| Frequency | Port |

| No. | band | A | B | C | D |
|---|---|---|---|---|---|
| 1 | Band3 | ON | OFF | OFF | OFF |
| 2 | Band7 | OFF | ON | OFF | OFF |
| 3 | Band1 | OFF | OFF | ON | OFF |
| 4 | Band3&7 | ON | ON | OFF | OFF |
| 5 | Band7&1 | OFF | ON | ON | ON |

In the examples of No. 1˜3, signals of a single frequency band are transmitted and received. The examples of Nos. 4 and 5 are the examples of CA, and signals of two frequency bands are simultaneously transmitted and received.

A description will be given of an example using a single frequency band. As presented in Nos. 1˜3 of Table 1, when a single frequency band is used, the switch 12 turns one port ON, and turns the other ports OFF.

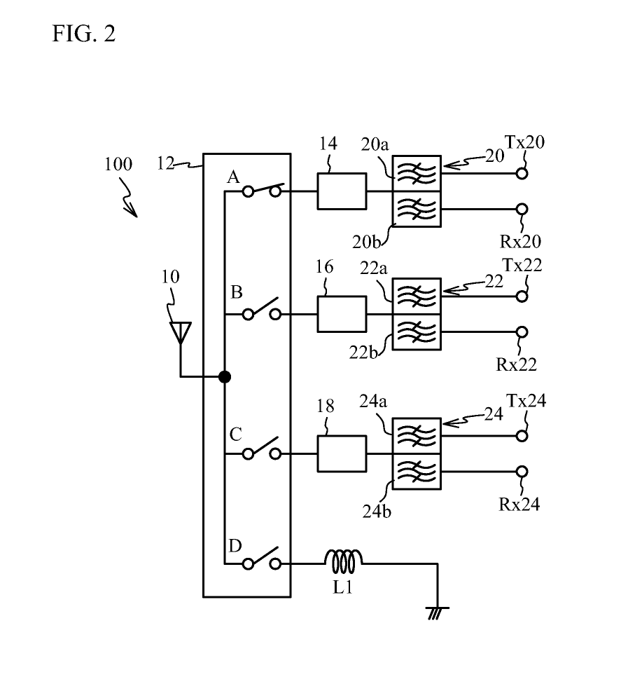

FIG. 2 is a block diagram illustrating the example of No. 1 in Table 1 that transmits and receives signals of Band3. The illustration of the IC 26 is omitted. As presented in FIG. 2 and Table 1, the switch 12 turns the port A ON, and turns the other ports OFF. A transmission signal is input from the transmit terminal Tx20 to the transmit filter 20a. The transmission signal is filtered by the transmit filter 20a, and then transmitted from the antenna 10 through the switch 12. A reception signal is received by the antenna 10, and input to the receive filter 20b through the switch 12. The reception signal filtered by the receive filter 20b is output from the receive terminal Rx20. The ports B and C are turned OFF, and thus the transmission signal and the reception signal are not input to the duplexers 22 and 24. In the examples of Nos. 2 and 3 in Table 1, signals are transmitted and received in the same manner as in the example of No. 1.

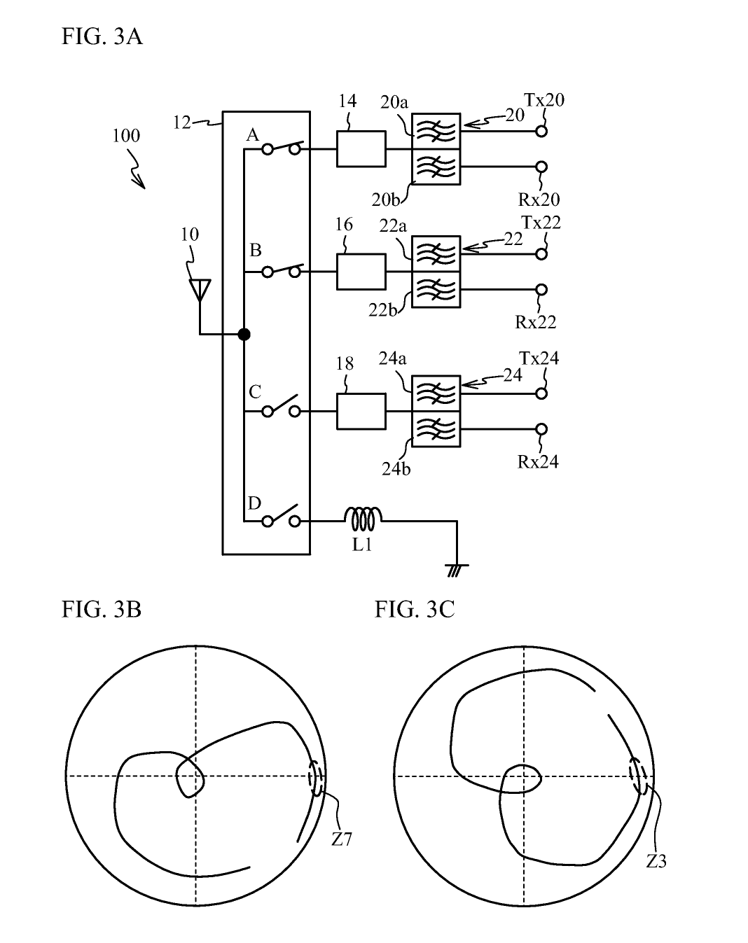

A description will next be given of an example of CA simultaneously using two frequency bands. In CA, two frequency bands are used as presented in Nos. 4 and 5 in Table 1. A description will now be given of the example of No. 4 that simultaneously transmits and receives a signal of Band3 and a signal of Band1. FIG. 3A is a block diagram illustrating the example of No. 4. As presented in FIG. 3A and Table 1, the switch 12 turns the ports A and B ON, and turns the ports C and D OFF.

FIG. 3B is a Smith chart illustrating impedance of the duplexer 20. The dashed-line ellipse in FIG. 3B indicates impedance Z7 in the frequency band (the transmit band and the receive band) of Band7. FIG. 3C is a Smith chart illustrating impedance of the duplexer 22. The dashed-line ellipse in FIG. 3C indicates impedance Z3 in the frequency band of Band3. The impedance means impedance as viewed from the switch 12. As illustrated in FIG. 3B, the impedance Z7 is located near the right edge of the Smith chart. That is to say, the impedance Z7 reaches infinity, or is close to infinity. As illustrated in FIG. 3C, the impedance Z3 is located at the right edge of the Smith chart. That is to say, the duplexer 20 is opened in the frequency band of the duplexer 22 while the duplexer 22 is opened in the frequency band of the duplexer 20 as viewed from the switch 12. Therefore, the signal of Band3 flows with difficulty through the duplexer 22 and easily flows through the duplexer 20. The signal of Band7 flows with difficulty through the duplexer 20 and easily flows through the duplexer 22. As a result, the signal of Band3 and the signal of Band7 can be simultaneously transmitted and received.

However, as described later in a comparative example, it is difficult to open the duplexer 22, which is opened to Band3, also to Band1. The first embodiment optimizes the duplexer with respect to two bands by using the inductor L1.

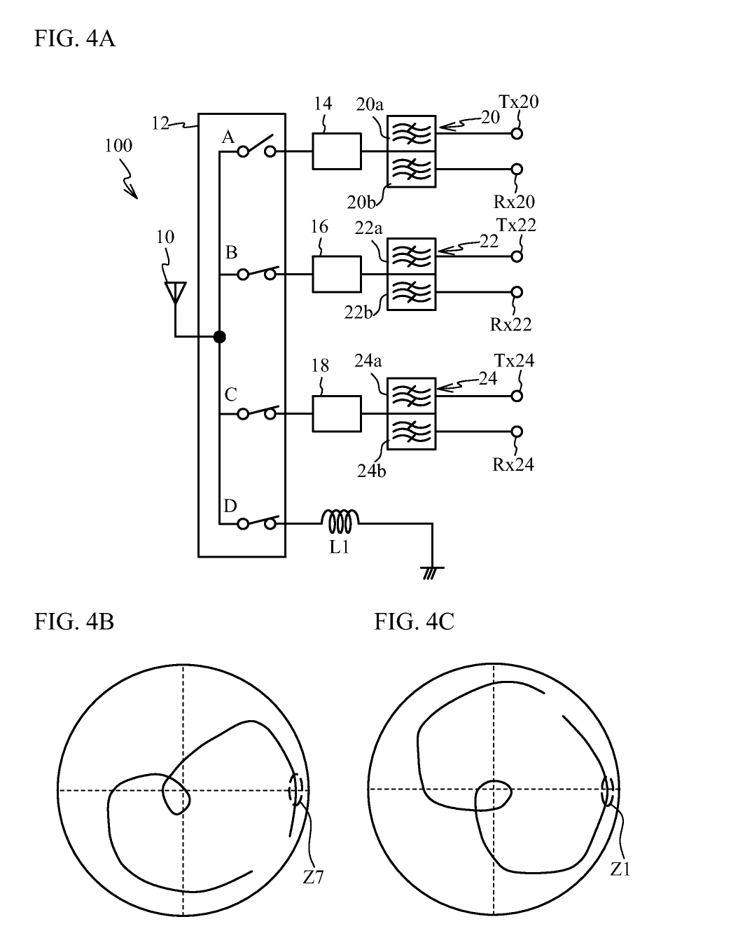

A description will be given of the example of No. 5 in Table 1 that simultaneously transmits and receives a signal of Band7 and a signal of Band1. FIG. 4A is a block diagram illustrating the example of No. 5. As presented in FIG. 4A and Table 1, the switch 12 turns the ports B, C, and D ON, and turns the port A OFF.

FIG. 4B is a Smith chart illustrating impedance of the duplexer 24. The dashed-line ellipse in FIG. 4B indicates impedance Z7 in the frequency band of Band7. FIG. 4C is a Smith chart illustrating impedance of the duplexer 22. The dashed-line ellipse in FIG. 4C indicates impedance Z1 in the frequency band of Band1. As illustrated in FIG. 4B, the impedance Z7 is located at the right edge of the Smith chart. As illustrated in FIG. 4C, the impedance Z1 is located at the right edge. As described above, in the first embodiment, the connection of the inductor L1 opens the duplexers 22 in the frequency band of the duplexer 24 and opens the duplexer 24 in the frequency band of the duplexers 22 as viewed from the switch 12. Thus, the signal of Band7 flows with difficulty through the duplexer 24, and easily flows through the duplexer 22. The signal of Band1 flows with difficult through the duplexer 22, and easily flows through the duplexer 24. The leakage of the signal is suppressed, and thereby, good frequency characteristics with reduced signal loss can be obtained. The signals of two frequency bands (Band1 and Band7) can be simultaneously transmitted and received.

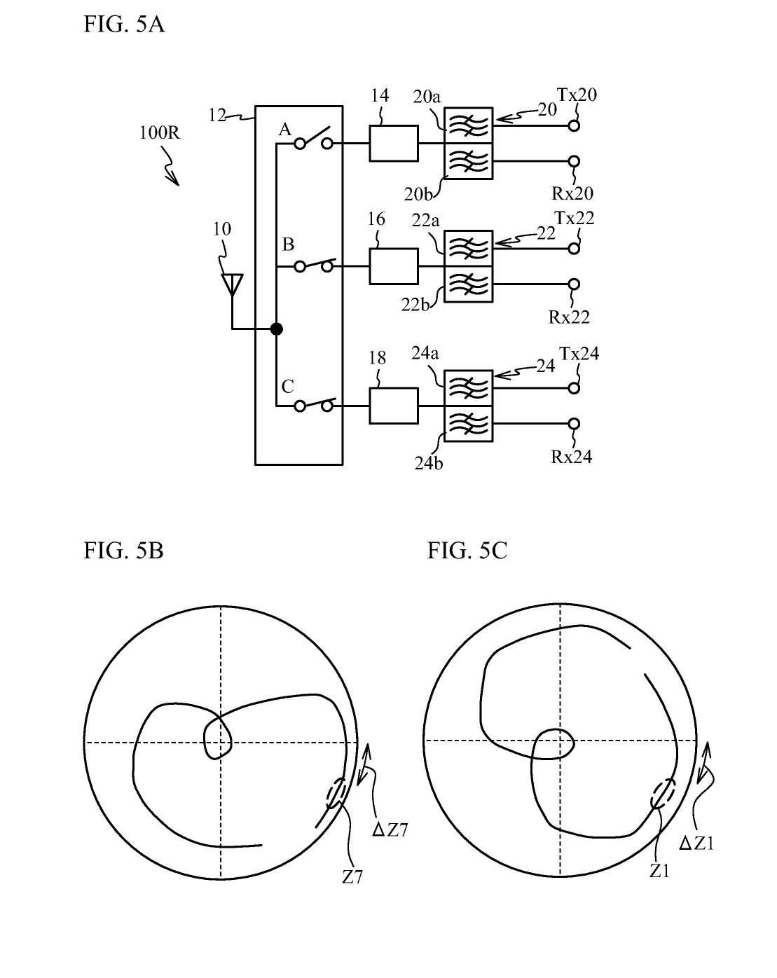

A description will be given of a comparative example. FIG. 5A is a block diagram illustrating an electronic circuit 100R in accordance with a comparative example. As illustrated in FIG. 5A, the inductor L1 is not provided. The illustration of the IC 26 is omitted. Table 2 presents a relationship between frequency bands and ports.

TABLE 2

| | | Port | | |
|---|---|---|---|---|
| No. | Frequency band | A | B | C |
| 6 | Band3 | ON | OFF | OFF |
| 7 | Band7 | OFF | ON | OFF |
| 8 | Band1 | OFF | OFF | ON |
| 9 | Band3&7 | ON | ON | OFF |
| 10 | Band7&1 | OFF | ON | ON |

As presented in Table 2, when signals of a single frequency band are transmitted and received (Nos. 6˜8), the switch 12 turns one port ON and turns the other two ports OFF in the same manner as in the first embodiment. When CA is performed (Nos. 9 and 10), the switch 12 turns two ports ON, and turns the other one port OFF. The duplexer 20 is opened in the passband of the duplexer 22 while the duplexer 22 is opened in the passband of the duplexer 20 as illustrated in FIG. 3B and FIG. 3C also in the comparative example.

A description will be given of the example of No. 10 that transmits and receives a signal of Band7 and a signal of Band1. As presented in FIG. 5A and Table 2, the switch 12 turns the ports B and C ON, and turns the port A OFF. FIG. 5B is a Smith chart illustrating impedance of the duplexer 24. FIG. 5C is a Smith chart illustrating impedance of the duplexer 22. The matching circuit 18 is optimized with respect to Band3, and therefore, the impedance Z7 is located below the right edge of the Smith chart as illustrated in FIG. 5B. As illustrated in FIG. 5C, the impedance Z1 is located below the right edge. As described above, in the comparative example, the duplexer 22 is not opened in the passband of the duplexer 24 and the duplexer 24 is not opened in the passband of the duplexer 22. Therefore, the signal of Band7 leaks to the duplexer 24 and the signal of Band1 leaks to the duplexer 22. As described above, it is difficult to optimize the duplexer 22 with respect to both Band3 and Band1.

The reactance component of the duplexer 22 in the frequency band of Band1 is approximately equal to the reactance component of the duplexer 24 in the frequency band of Band7. That is to say, the shifted amount ΔZ7 of the impedance Z7 from the right edge of the Smith chart illustrated in FIG. 5B is approximately equal to the shifted amount ΔZ1 of the impedance Z1 from the right edge illustrated in FIG. 5C. Therefore, when the impedances of the duplexers 22 and 24 are rotated to the upper side of the Smith chart by approximately the same amount, the impedances approach infinity. In the first embodiment, as illustrated in FIG. 4A, the inductor L1 is commonly connected to the duplexers 22 and 24. As a result, the impedances of the duplexers 22 and 24 are changed by the same amount. Therefore, the impedance in the frequency band of the other duplexer can be made to be infinity. It is preferable that the impedance reaches infinity or is close to infinity, but it is sufficient if it is high enough for practical use. For example, the impedance is preferably as high as the impedance with which the signal in the frequency band of the other duplexer flows with difficulty.

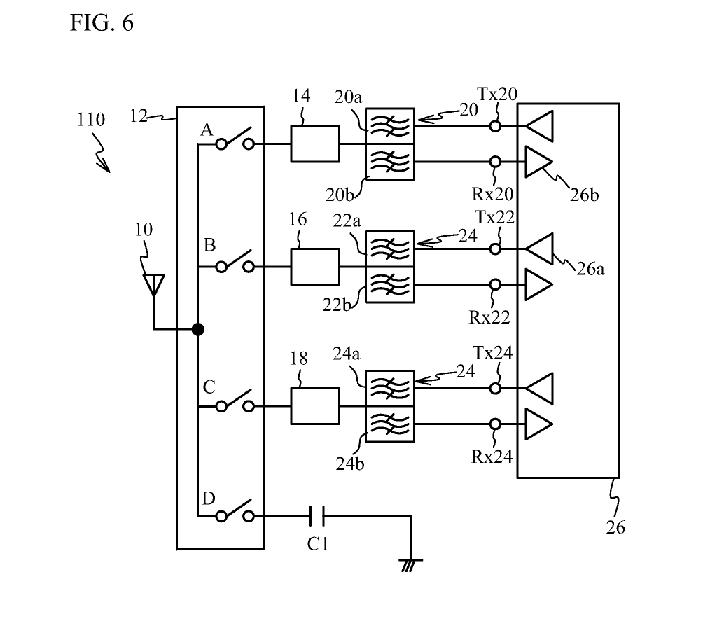

A variation of the first embodiment uses a capacitor C1. FIG. 6 is a block diagram illustrating an electronic circuit 110 in accordance with the variation of the first embodiment. As illustrated in FIG. 6, a first end of the capacitor C1 is coupled to the port D, and a second end is grounded. When the impedance is shifted to the upper side from the right edge of the Smith chart, the impedance can be made to approach infinity by rotating the impedance to the lower side by the capacitor C1. As illustrated in FIG. 3A and FIG. 6, the duplexer can be opened by connecting the inductor or the capacitor to the switch 12. The structure is simple, and thereby the electronic circuit can be reduced in cost and size.

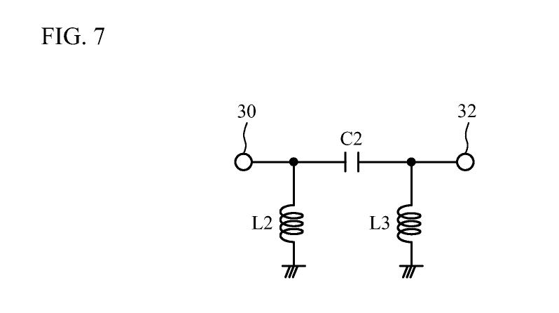

A description will be given of examples of the matching circuits 14, 16, and 18. FIG. 7 is a circuit diagram illustrating the matching circuit. As illustrated in FIG. 7, a capacitor C2 is connected in series between a terminal 30 and a terminal 32. A first end of an inductor L2 is connected between the terminal 30 and the capacitor C2, and a first end of an inductor L3 is connected between the capacitor C2 and the terminal 32. Second ends of the inductors L2 and L3 are grounded. The matching circuit may be used instead of the inductor L1 in FIG. 1. That is to say, it is sufficient if a circuit including at least one of an inductor and a capacitor is coupled to the port D of the switch 12.

### Second Embodiment

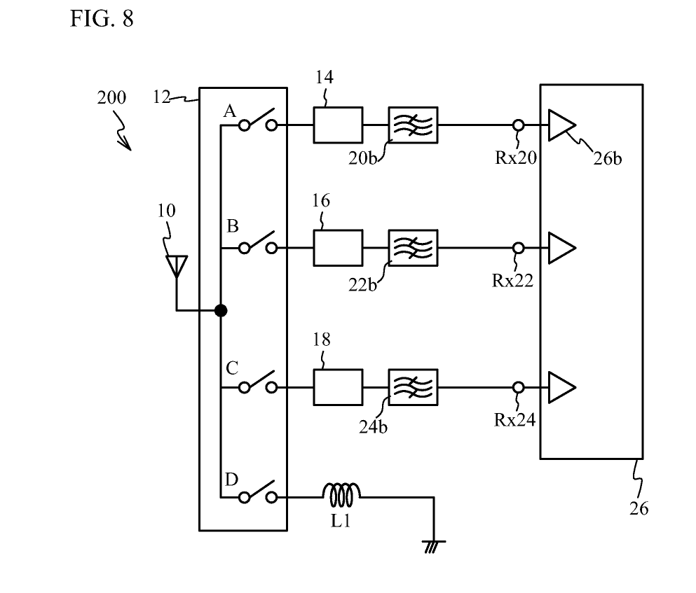

A second embodiment provides a filter instead of a duplexer. FIG. 8 is a block diagram illustrating an electronic circuit 200 in accordance with the second embodiment. As illustrated in FIG. 8, the receive filter 20b is coupled to the port A, the receive filter 22b is coupled to the port B, and the receive filter 24b is coupled to the port C. The switch 12 selects the ports A˜D in the manner presented in Table 1. As with the example illustrated in FIG. 3B, the receive filter 20b is opened in the passband of Band7, and as with the example illustrated in FIG. 3C, the receive filter 22b is opened in the passband of Band3. The connection of the inductor L1 opens the receive filter 24b in the passband of Band7 in the same manner as in the example illustrated in FIG. 4B, and opens the receive filter 22b in the passband of Band1 in the same manner as in the example illustrated in FIG. 4C. In the second embodiment, signals of two frequency bands can be received, and good frequency characteristics can be obtained as is the case with the first embodiment.

Only the receive filter or only the transmit filter may be provided. Both the duplexer and the filter may be provided. For example, the receive filter 20b is coupled to the port A, the receive filter 24b is coupled to the port C, and the duplexer 22 is coupled to the port B. In the example of No. 4 in Table 1, the reception of signals of Band3 and Band7 and the transmission of a signal of Band7 can be simultaneously performed. In the example of No. 5 in Table 1, the reception of signals of Band1 and Band7 and the transmission of a signal of Band7 can be simultaneously performed.

The filter may be a boundary acoustic wave filter, an acoustic wave filter such as a filter using a Film Bulk Acoustic Resonator (FBAR), or a filter other than the acoustic wave filter. The switch 12 may include two ports or four or more ports. The number of filters and duplexers connected to the switch 12 may be two or four or more.

### Third Embodiment

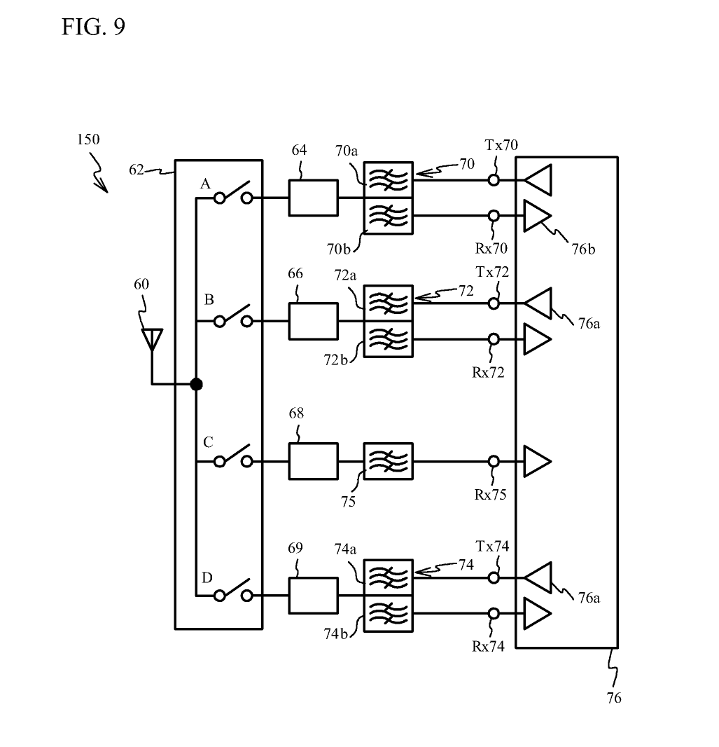

A third embodiment performs CA by using a duplexer and a filter. FIG. 9 is a block diagram illustrating an electronic circuit 150 in accordance with the third embodiment. As illustrated in FIG. 9, the electronic circuit 150 includes a switch 62, matching circuits 64, 66, 68 and 69, duplexers 70, 72 and 74, a receive filter 75, and an integrated circuit (IC) 76. The IC 76 includes power amplifiers (PA) 76a and low noise amplifiers (LNA) 76b. The IC 76 performs signal processing such as up-conversion and down-conversion. The PA 76a amplifies a transmission signal. The LNA 76b amplifies a reception signal. The electronic circuit 150 is used in a module for communication devices, for example.

The duplexer 70 (a first duplexer) includes a transmit filter 70a and a receive filter 70b. The duplexer 72 (a second duplexer) includes a transmit filter 72a and a receive filter 72b. The duplexer 74 (a third duplexer) includes a transmit filter 74a and a receive filter 74b. Each filter is a bandpass filter such as a surface acoustic wave (SAW) filter.

The switch 62 is a semiconductor switch including four ports A˜D. A first end of the matching circuit 64 (a first matching circuit) is coupled to the port A (a first port), and a second end thereof is coupled to first ends of the transmit filter 70a and the receive filter 70b. A second end of the transmit filter 70a is coupled to the PA 76a through a transmit terminal Tx70 (a first terminal). A second end of the receive filter 70b is coupled to the LNA 76b through a receive terminal Rx70 (a first terminal). The port B (a second port), the matching circuit 66 (a second matching circuit), the duplexer 72, a transmit terminal Tx72 and a receive terminal Rx72 (second terminals), the PA 76a, and the LNA 76b are connected in the same manner as the port A through the IC 76. A first end of the matching circuit 68 (a third matching circuit) is coupled to the port C (a third port), and a second end thereof is coupled to a first end of the receive filter 75 (an impedance matching unit). A second end of the receive filter 75 is coupled to the LNA 76b through a receive terminal Rx75 (a third terminal). The port D (a fourth port), the matching circuit 69 (a fourth matching circuit), the duplexer 74, a transmit terminal Tx74 and a receive terminal Rx74 (fourth terminals), the PA 76a, and the LNA 76b are connected in the same manner as the port A through the IC 76. The matching circuits 64, 66, 68 and 69 match impedance between the duplexers, impedance between the duplexer and the filter, impedance between an antenna 60 and each duplexer, and impedance between the antenna 60 and the receive filter 75.

The duplexers support frequency bands different from each other. The duplexer 70 supports, for example, W-CDMA (Wideband Code Division Multiple Access) Band4. The duplexer 72 supports, for example, W-CDMA Band7. The duplexer 74 supports, for example, W-CDMA Band1. The receive filter 75 supports a receive band of W-CDMA Band7. Hereinafter, Band may be solely described without describing W-CDMA. In addition, a receive band may be described as Rx, and a transmit band may be described as Tx.

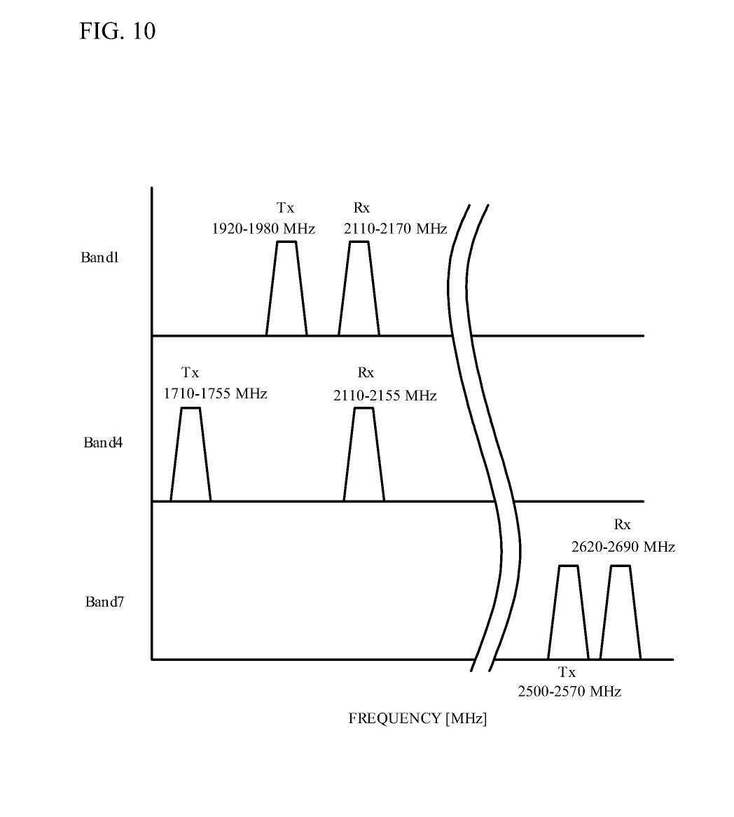

FIG. 10 is a schematic view illustrating frequencies of each band, and showing frequencies of Band1, Band4, and Band7 in this order from the upper side. The horizontal axis represents frequency. As illustrated in FIG. 10, the spacing between the high end of the receive band and the low end of the transmit band in Band7 is 190 MHz and less than the spacing between the high end of the receive band and the low end of the transmit band in Band4 which is 445 MHz. The spacing between the high end of the receive band and the low end of the transmit band in Band1 is 250 MHz. The spacing is a difference between the frequency at the high end of the receive band and the frequency at the low end of the transmit band.

A description will be given of transmission and reception of signals. The switch 62 selects a port from the ports A˜D depending on the frequency band to be used, and connects it to the antenna 60. Table 3 presents a relationship between frequency bands and ports.

TABLE 3

Port

| No. | Frequency band | A | B | C | D |
|---|---|---|---|---|---|
| 51 | Band4 | ON | OFF | OFF | OFF |
| 52 | Band7 | OFF | ON | OFF | OFF |
| 53 | Band1 | OFF | OFF | OFF | ON |
| 54 | Band4Rx, 7Tx&Rx | ON | ON | OFF | OFF |
| 55 | Band4Tx&Rx, 7Rx | ON | OFF | ON | OFF |
| 56 | Band4Rx, 7Tx&Rx | OFF | ON | OFF | ON |
| 57 | Band1Rx, 7Tx&Rx | OFF | ON | OFF | ON |

In the examples of Nos. 51˜53, signals of a single frequency band are transmitted and received. The examples of Nos. 54˜57 are the examples of CA, and signals of two frequency bands are simultaneously transmitted and received. The third embodiment describes the examples of Nos. 54 and 55 out of the examples of Nos. 54˜57. The examples of Nos. 56 and 57 will be described in a fourth embodiment.

A description will be given of an example that uses a single frequency band. As presented in Nos. 51˜53 in Table 3, when a single frequency band is used, the switch 62 turns one port ON and turns the other ports OFF.

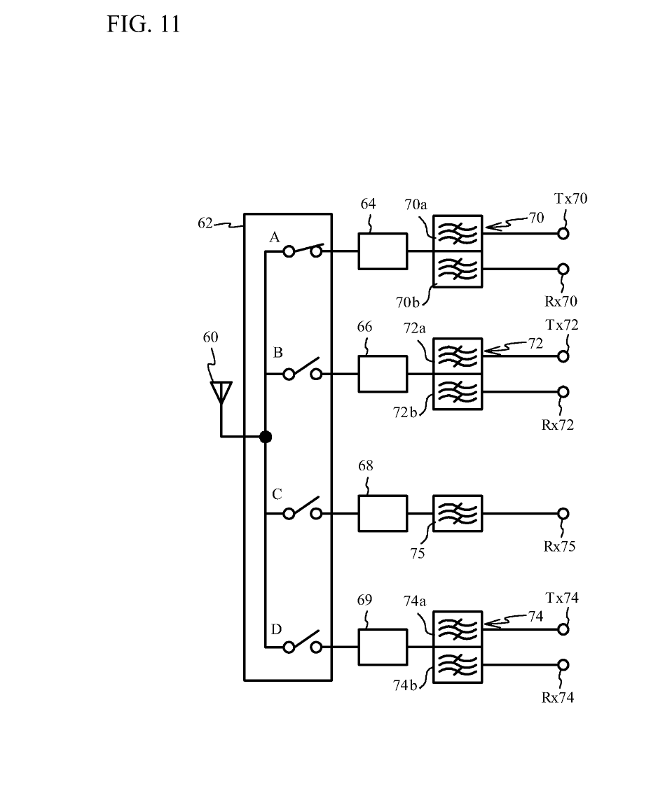

FIG. 11 is a block diagram illustrating the example of No. 51 in Table 3 that transmits and receives signals of Band4. The illustration of the IC 76 is omitted. As presented in FIG. 11 and Table 3, the switch 62 turns the port A ON and turns the other ports OFF. A transmission signal is input from the transmit terminal Tx70 to the transmit filter 70a. The transmission signal is filtered by the transmit filter 70a and then transmitted from the antenna 60 through the switch 62. A reception signal is received by the antenna 60 and input to the receive filter 70b through the switch 62. The reception signal filtered by the receive filter 70b is output from the receive terminal Rx70. The ports B, C and D are turned OFF. As a result, the transmission signal and the reception signal are not input to the duplexers 72 and 74 and the receive filter 75. In the examples of Nos. 52 and 53 in Table 3, signals are transmitted and received in the same manner as in the example of No. 51.

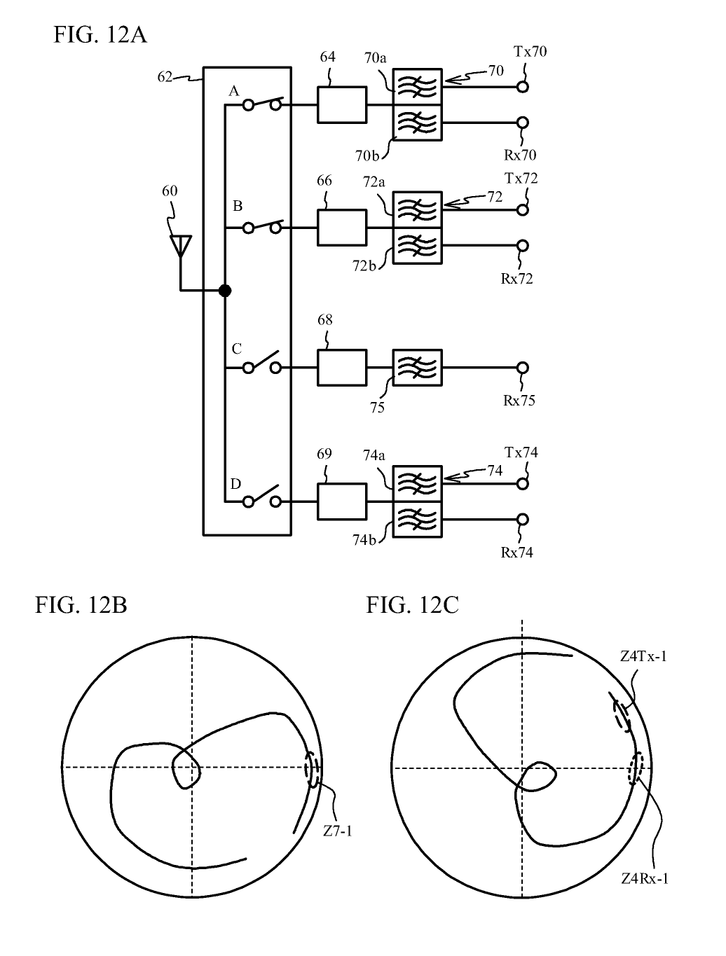

A description will be given of an example of CA simultaneously using two frequency bands. In CA, two frequency bands are used as presented in Nos. 54˜57 in Table 3. A description will be given of the example of No. 54 that receives a signal of Band4 and transmits and receives signals of Band7. FIG. 12A is a block diagram illustrating the example of No. 54. As presented in FIG. 12A and Table 3, the switch 62 turns the ports A and B ON and turns the ports C and D OFF.

FIG. 12B is a Smith chart illustrating impedance of the duplexer 70. The dashed-line ellipse in FIG. 12B indicates impedance Z7-1 of the duplexer 70 in the frequency band (the transmit band and the receive band) of Band7. FIG. 12C is a Smith chart illustrating impedance of the duplexer 72. The dashed-line ellipse in FIG. 12C indicates impedance Z4Tx-1 of the duplexer 72 in the transmit band of Band4 (Band4Tx). The dotted-line ellipse indicates impedance Z4Rx-1 of the duplexer 72 in the receive band of Band4 (Band4Rx). The impedance means impedance as viewed from the switch 62.

As illustrated in FIG. 12B, the impedance Z7-1 is located near the right edge of the Smith chart. That is to say, the impedance Z7-1 reaches infinity or is close to infinity. As illustrated in FIG. 12C, the impedance Z4Rx-1 is located at the right edge of the Smith chart. The impedance Z4Tx-1 is shifted to the upper side from the right edge of the Smith chart. The duplexer 70 is opened to Band7Tx and Band7Rx used in the example of No. 54 while the duplexer 72 is opened to Band4Rx. That is to say, as viewed from the switch 62, the duplexer 70 is opened in the frequency band of the duplexer 72 while the duplexer 72 is opened in the frequency band of the duplexer 70. As a result, signals in Band7Tx and Band7Rx flow with difficulty through the duplexer 70 and easily flow through the duplexer 72. A signal in Band4Rx flows with difficulty through the duplexer 72 and easily flows through the duplexer 70. As a result, the reception of a signal of Band4 and the transmission and reception of signals of Band7 are simultaneously performed.

As illustrated in FIG. 10, the spacing between Tx and Rx is small in Band7. Hence, the duplexer 70 can be opened to both Tx and Rx of Band7 as illustrated in FIG. 12B. As illustrated in FIG. 10, the spacing between Tx and Rx of Band4 is large. Hence, it is difficult to open the duplexer 72 to both Tx and Rx of Band4 as illustrated in FIG. 12C. When the duplexer 72 is opened to Band4Rx, it is not opened to Band4Tx. Therefore, when a signal of Band4 is transmitted under the configuration illustrated in FIG. 12A, the transmission signal of Band4 leaks to the duplexer 72. The leakage of the signal deteriorates frequency characteristics.

The third embodiment performs CA including the transmission of a signal of Band4 by using the receive filter 75. A description will be given of the example of No. 55 in Table 3 that transmits and receives signals of Band4 and receives a signal of Band7.

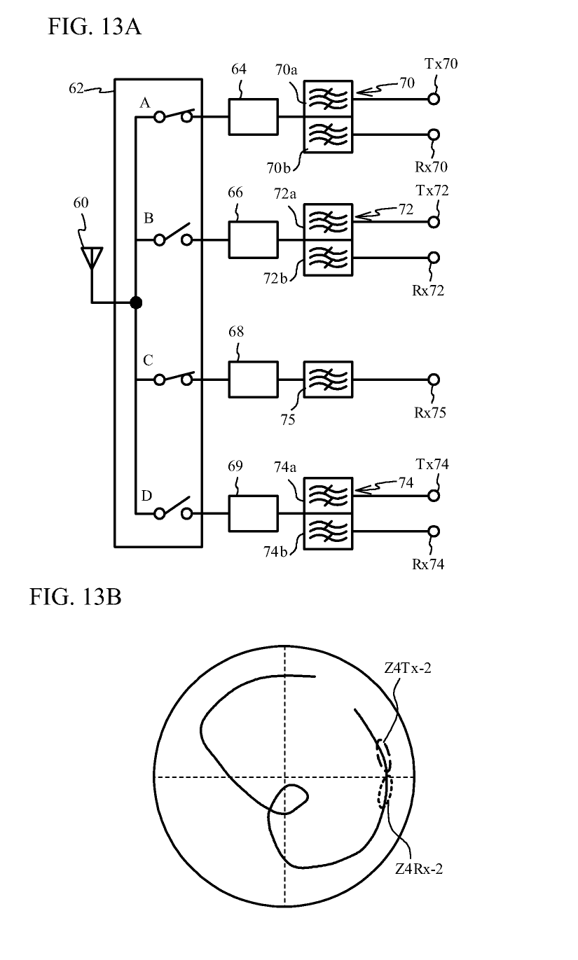

FIG. 13A is a block diagram illustrating the example of No. 55. As presented in FIG. 13A and Table 3, the switch 62 turns the ports A and C ON, and turns the ports B and D OFF.

The impedance of the duplexer 70 is the same as that illustrated in FIG. 12B. FIG. 13B is a Smith chart illustrating impedance of the receive filter 75. The dashed-line ellipse in FIG. 13B indicates impedance Z4Tx-2 of the receive filter 75 in Band4Tx. The dotted-line ellipse indicates impedance Z4Rx-2 of the receive filter 75 in Band4Rx. As illustrated in FIG. 13B, the impedances Z4Tx-2 and Z4Rx-2 are located near the right edge of the Smith chart. That is to say, the receive filter 75 is opened to Band4Tx and Bnad4Rx. The filter functions as a capacitive impedance. Compared to the duplexer 72 including the transmit filter 72a, the receive filter 75 may be regarded as the duplexer in which the capacitive impedance is removed. As a result, the impedance is rotated to the real axis direction, and the impedances Z4Tx-2 and Z4Rx-2 approach infinity.

As described above, the third embodiment performs CA by using the duplexer 70 and the receive filter 75 having the same receive band as the duplexer 72. As viewed from the switch 62, the duplexer 70 is opened in the frequency band of the receive filter 75 and the receive filter 75 is opened in the frequency band of the duplexer 70. As a result, the signal of Band1 flows with difficulty through the duplexer 70 and easily flows through the receive filter 75. The signal of Band4 flows with difficulty through the receive filter 75 and easily flows through the duplexer 70. As the leakage of the signal is suppressed, good frequency characteristics with reduced signal loss can be obtained.

### Fourth Embodiment

The fourth embodiment performs CA of No. 56 in Table 3 by using the duplexer 74. The fourth embodiment also uses the electronic circuit 150 illustrated in FIG. 9. As illustrated in FIG. 10, Band1Rx and Band4Rx overlap each other. The receive filter 74b passing a signal of Band1Rx also passes a signal of Band4Rx. Therefore, the receive filter 74b functions as a receive filter supporting Band4.

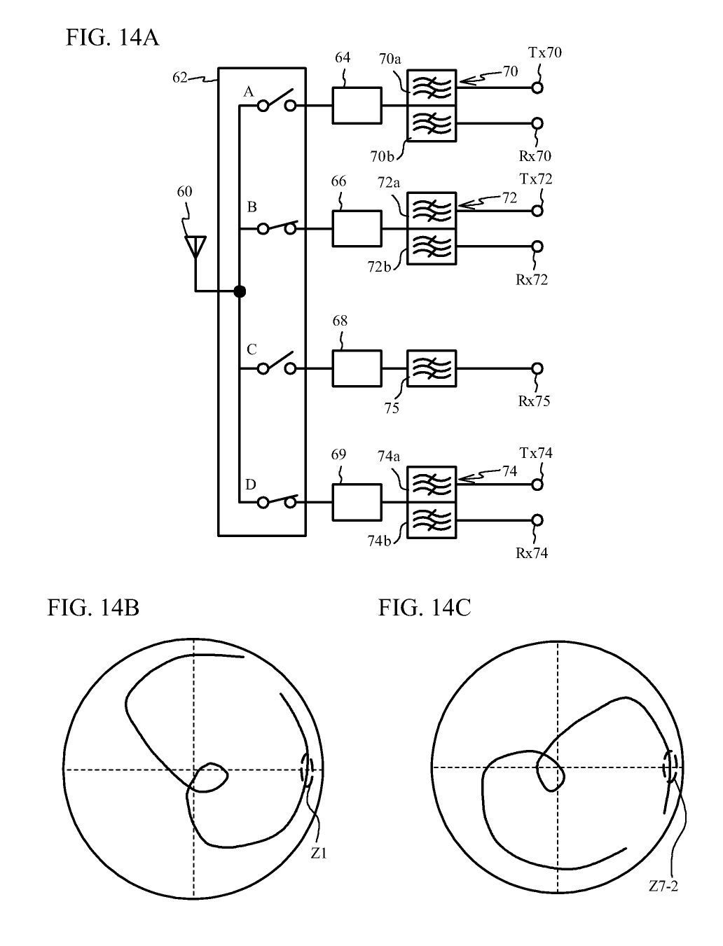

FIG. 14A is a block diagram illustrating the example of No. 56. As presented in FIG. 14A and Table 3, the switch 62 turns the ports B and D ON, and turns the ports A and C OFF.

FIG. 14B is a Smith chart illustrating impedance of the duplexer 72. A dashed-line ellipse in FIG. 14B indicates impedance Z1 of the duplexer 72 in the communication band of Band1. The impedance Z1 is located at the right edge of the Smith chart. As illustrated in FIG. 10, the spacing between Tx and Rx of Band1 is less than the spacing between Tx and Rx of Band4. Therefore, the duplexer 72 can be opened to both Tx and Rx of Band1. FIG. 14C is a Smith chart illustrating impedance of the duplexer 74. The dashed-line ellipse in FIG. 14C indicates impedance Z7-2 of the duplexer 74 in the communication band of Band7. The impedance Z7-2 is located at the right edge of the Smith chart. As presented, the duplexer 72 is opened in the frequency band of the duplexer 74 while the duplexer 74 is opened in the frequency band of the duplexer 72. As is the case with the third embodiment, the fourth embodiment can obtain good frequency characteristics.

The use of the example illustrated in FIG. 14A achieves CA of No. 57 in Table 3. This is because the duplexer 72 is opened to the communication band of Band1 and the duplexer 74 is opened to the communication band of Band7. In addition to the examples of Nos. 56 and 57 in Table 3, the use of the example of FIG. 14A also achieves CA of Band1Tx&Rx and Band7Rx, CA of Band1Tx&Rx and Band7Tx&Rx. Any of the examples of No. 54 and No. 56 in Table 3 may be used to achieve CA of Band4Rx and Band7Tx and Rx.

### Fifth Embodiment

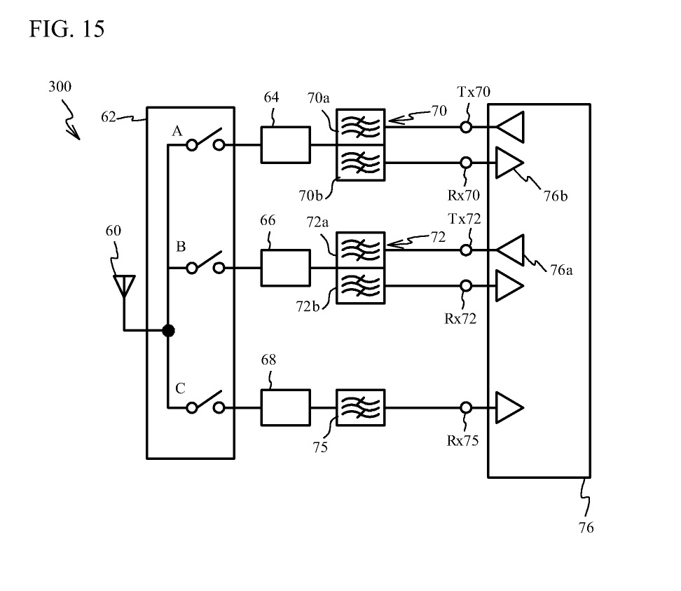

In a fifth embodiment, the switch 62 includes three ports. The number of ports may be changed depending on CA to be performed. FIG. 15 is a block diagram illustrating an electronic circuit 300 in accordance with the fifth embodiment. As illustrated in FIG. 15, the switch 62 includes ports A˜C. The electronic circuit 300 can perform the communication of Nos. 51, 52, 54 and 55 in Table 3.

The filter may be a boundary acoustic wave filter, an acoustic wave filter such as a filter using a Film Bulk Acoustic Resonator (FBAR), or a filter other than the acoustic wave filter. The switch 62 may include four or more ports. The number of filters connected to the switch 62 may be two or more, and the number of duplexers may be four or more.

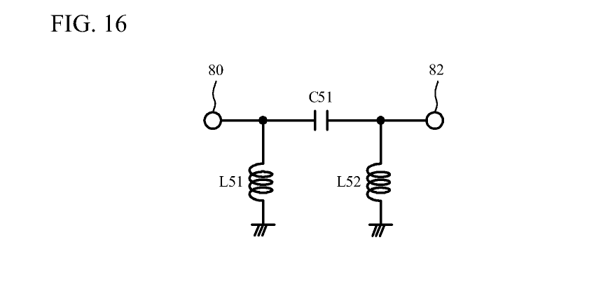

The matching circuits 64, 66, 68 and 69 may be a circuit including at least one of an inductor and a capacitor, for example. A description will be given of an example of the matching circuit. FIG. 16 is a circuit diagram illustrating the matching circuit. As illustrated in FIG. 16, a capacitor C51 is connected in series between a terminal 80 and a terminal 82. A first end of an inductor L51 is connected between the terminal 80 and the capacitor C51, and a first end of an inductor L52 is connected between the capacitor C51 and the terminal 82. Second ends of the inductors L51 and L52 are grounded.

Although the embodiments of the present invention have been described in detail, it is to be understood that the various change, substitutions, and alterations could be made hereto without departing from the spirit and scope of the invention.

What is claimed is:

1. An electronic circuit comprising:
a switch including ports and selecting a port to be connected to an antenna from the ports;
a first filter connected between a first port out of the ports and a first terminal;
a second filter connected between a second port out of the ports and a second terminal and having a frequency band different from a frequency band of the first filter; and
an impedance matching unit of which a first end is coupled to a third port out of the ports.

2. The electronic circuit according to claim 1, wherein
the impedance matching unit is a first matching circuit of which a first end is coupled to the third port and of which a second end is grounded, and
the switch selects the first port, the second port, and the third port out of the ports when at least one of transmission and reception of a signal in a frequency band of the first filter and at least one of transmission and reception of a signal in a frequency band of the second filter are simultaneously performed.

3. The electronic circuit according to claim 2, wherein
the second filter is opened in a frequency in the frequency band of the first filter as viewed from the switch while the first filter is opened in a frequency in the frequency band of the second filter as viewed from the switch in a case where the switch selects the first port, the second port, and the third port.

4. The electronic circuit according to claim 2, wherein
a reactance component of the second filter in a frequency in the frequency band of the first filter as viewed from the switch is equal to a reactance component of the first filter in a frequency in the frequency band of the second filter as viewed from the switch in a case where the switch selects the first port and the second port and does not select the third port.

5. The electronic circuit according to claim 2, wherein
a first duplexer includes the first filter and a second duplexer includes the second filter, and
the switch selects the first port, the second port, and the third port out of the ports when at least one of transmission and reception of a signal in a frequency band of the first duplexer and at least one of transmission and reception of a signal in a frequency band of the second duplexer are simultaneously performed.

6. The electronic circuit according to claim 2, further comprising:
a third filter connected between a fourth port out of the ports and a third terminal and having a frequency band different from frequency bands of the first filter and the second filter, wherein
the switch selects the first port and the fourth port and does not select the second port or the third port when at least one of transmission and reception of a signal in the frequency band of the first filter and at least one of transmission and reception of a signal in a frequency band of the third filter are simultaneously performed.

7. The electronic circuit according to claim 6, wherein
the third filter is opened in a frequency in the frequency band of the first filter as viewed from the switch while the first filter is opened in a frequency in the frequency band of the third filter in a case where the switch selects the first port and the fourth port and does not select the second port or the third port.

8. The electronic circuit according to claim 6, wherein
a first duplexer includes the first filter and a third duplexer includes the third filter, and
the switch selects the first port and the fourth port and does not select the second port or the third port when at least one of transmission and reception of a signal in a frequency band of the first duplexer and at least one of transmission and reception of a signal in a frequency band of the third duplexer are simultaneously performed.

9. The electronic circuit according to claim 2, wherein
the first matching circuit includes at least one of an inductor and a capacitor.

10. The electronic circuit according to claim 2, further comprising:
a second matching circuit connected between the first port and the first filter; and
a third matching circuit connected between the second port and the second filter.

11. The electronic circuit according to claim 1, further comprising:
a first duplexer including the first filter and having a first frequency band; and
a second duplexer including the second filter and having a second frequency band of which spacing between a receive band and a transmit band is less than spacing between a receive band and a transmit band of the first frequency band, wherein
the impedance matching unit is connected between the third port and a third terminal and includes a third filter having a receive band overlapping with a receive band of the second frequency band.

12. The electronic circuit according to claim 11, wherein
the switch selects the first port and the third port and does not select the second port when transmission and reception of signals in the first frequency band and reception of a signal in the second frequency band are simultaneously performed.

13. The electronic circuit according to claim 11, wherein
the switch selects the first port and the second port and does not select the third port when reception of a signal in the first frequency band and transmission and reception of signals in the second frequency band are simultaneously performed.

14. The electronic circuit according to claim 12, wherein
the third filter is opened in a frequency in the transmit band and the receive band of the first frequency band as viewed from the switch while the first duplexer is opened in a frequency in the receive band of the second frequency band as viewed from the switch in a case where the switch selects the first port and the third port.

15. The electronic circuit according to claim 11, further comprising:
a first matching circuit connected between the first port and the first duplexer;
a second matching circuit connected between the second port and the second duplexer; and
a third matching circuit connected between the third port and the third filter.

16. The electronic circuit according to claim 11, further comprising:
a third duplexer connected between a fourth port out of the ports and a fourth terminal and having a third frequency band of which spacing between a receive band and a transmit band is less than the spacing between the receive band and the transmit band of the first frequency band and of which the receive band overlaps with the receive band of the first frequency band, wherein
the switch selects the second port and the fourth port and does not select the first port or the third port when reception of a signal in the first frequency band and transmission and reception of signals in the second frequency band are simultaneously performed.

17. The electronic circuit according to claim 16, wherein
the second duplexer is opened in a frequency in the receive band of the first frequency band as viewed from the switch while the third duplexer is opened in a frequency in the transmit band and the receive band of the second frequency band as viewed from the switch in a case where the switch selects the second port and the fourth port.

18. The electronic circuit according to claim 16, further comprising:
a fourth matching circuit connected between the fourth port and the third duplexer.

19. The electronic circuit according to claim 13, wherein
the second duplexer is opened in a frequency in the receive band of the first frequency band as viewed from the switch while the first duplexer is opened in a frequency in the transmit band and the receive band of the second frequency band as viewed from the switch in a case where the switch selects the first port and the second port.
